(19) United States
(12) Patent Application Publication
(10) Pub. No.: US 2025/0167524 A1
(43) Pub. Date: May 22, 2025

(54) QUANTUM DOT DISTRIBUTED REFLECTOR LASER

(71) Applicant: Junko Makino, Irvine, CA (US)

(72) Inventor: Toshihiko Makino, Irvine, CA (US)

(21) Appl. No.: 18/744,073

(22) Filed: Jun. 14, 2024

Related U.S. Application Data
(60) Provisional application No. 63/628,103, filed on Jun. 23, 2023.

(51) Int. Cl. H01S 5/34; H01S 5/12; H01S 5/125

(52) U.S. Cl. CPC H01S 5/341; H01S 5/1228; H01S 5/125

(57) ABSTRACT

The invention provides a distributed reflector (DR) semiconductor laser, comprising two cavity sections which are composed of a distributed feedback (DFB) section and a distributed Bragg reflector (DBR) section. The active region of the DR laser is formed of quantum dot (QD) layers and the two sections have separate electrodes. The QD layers in the DFB section provide optical gain, and the QD layers in the DBR section are biased just above transparent to provide a passive waveguide DBR.

### CROSS-REFERENCE TO RELATED APPLICATIONS

This application claims priority to and the benefit of U.S. Provisional Patent Application No. 63/628,103 filed on Jun. 23, 2023, the entirety of which is hereby incorporated by reference.

### BACKGROUND

### 1. Field

This invention relates to distributed reflector (DR) lasers for the optical transmitters in fiber optic network systems.

### 2. Description of the Related Art

Recent dramatic increase in the data capacity of the internet and related optical networks have required higher modulation speed of the optical transmitters. There have been three types of high-speed optical modulators: (1) directly modulated lasers (DML); (2) electro absorption (EA) modulators; and (3) Mach-Zehnder (MZ) modulators. The modulation bandwidths (BW) of the DMLs, the EA modulators, and the MZ modulators are limited to less than approximately 35 GHZ, 60 GHz, and 30 GHz, respectively.

The DML has the advantages of small size, low cost, simple structure, low power consumption, and the capability of integrating with other photonic devices. The BW of the DML is limited fundamentally by the relaxation resonance frequency ƒ_{R} (determined by “electron-photon (E-P) resonance”). To increase the BW, higher ƒ_{R} is required. A common approach for higher ƒ_{R} is to use a short laser cavity length, described, for example, in the article by W. Kobayashi, T. Ito, T. Yamanaka, T. Fujisawa, Y. Shibata, T. Kurosaki, M. Kohtoku, T. Tadokoro, H. Sanjoh, “50-Gb/s direct modulation of a 1.3-μm InGaAlAs-based DFB laser with a ridge waveguide structure”, IEEE J. Sel. Topic Quantum Electronics, vol. 19, no. 4, no. 1500908, July/August 2013. This article shows that the ƒ_{R} becomes maximum when the cavity length is reduced to 150 μm, and never exceeds approximately 26 GHz for further reducing the cavity length. Therefore, the ƒ_{R} is limited fundamentally by the E-P resonance.

To break the E-P resonance limit, there have been mainly three approaches: (1) DBR laser; (2) DFB laser with an integrated passive waveguide; and (3) DR laser consisting of a DFB laser section and a DBR section.

The first approach is to use the so called “detuned loading” effect, in DBR lasers. This is described, for example, in the article by O. Kjebon, R. Schatz, S. Lourdudoss, S. Nilsson, B. Stalnacke, and L. Backbom, “Two-section InGaAsP DBR-lasers at 1.55 μm wavelength with 31 GHz direct modulation bandwidth”, in Conf. Proc. PRM, Hyannis, MA, May 1997, pp. 665-668, paper, ThF4. As shown in the article, in the distributed Bragg reflector (DBR) laser composing a uniform active section and a passive DBR section, the record high modulation bandwidth of 31 GHz was achieved. This is due to the increase of the effective differential gain, which is obtained by the lasing at a steep slope of the DBR reflection spectrum (detuned loading). For the dynamic behavior of DBR lasers, a theoretical model has been developed by U. Feiste, “Optimization of modulation bandwidth in DBR lasers with detuned Bragg reflectors,” IEEE J. Quantum Electronics, vol. 34, no. 12, pp. 2371-2379 December 1998. This model is a general multimode model based on the traveling-wave equations. Under the assumption of the rigid single-mode operation (only one mode considered), the enhanced E-P resonance frequency can be expressed analytically as

$${f}_{R} = {χ}_{R} {f}_{R , FP} \qquad ( 1 )$$

$$with$$

$${χ}_{R} = \sqrt{{L}_{a} Re ( \frac{1 + i {α}_{H}}{{L}_{a} + {L}_{eff}} )} \qquad ( 2 )$$

where ƒ_{R,FP} is the relaxation resonance frequency of the Fabry Perot (FP) laser without grating, Lₐ is the active region length, α_{H} is the linewidth enhancement factor (so called, the Henry's factor), L_{eff} is the effective length of a DBR, given as

$${L}_{eff} = \frac{1}{2} {iv}_{g} \frac{d ln {r}_{Reff}}{d ω} {\vert}_{ω = {ω}_{s}} \qquad ( 3 )$$

v_{g} is the group velocity, r_{eff} is the amplitude reflectivity of the DBR, and ωₛ is the lasing angular frequency. We see from (1), (2), and (3) that ƒ_{R} is affected by α_{H} and L_{eff}. If the second mode is added to the dominant mode, the modulation response can exhibit another resonance peak (so called photon-photon (P-P) resonance) at some modulation frequency much higher than the E-P resonance frequency. One example simulation shows the P-P resonance frequency of about 60 GHz, which corresponds roughly to the frequency separation between the dominant mode and the second mode.

The second approach is to use the P-P resonance effect in the passive feedback lasers (PFL), in which a passive waveguide is integrated with a DFB laser. This is described, for example, in the article by U. Troppenz, J. Kreissl, M. Mohrle, C. Bornholdt, W. Rehbein, B. Sartorius, I. Woods, M. Schell, “40 Gbit/s directly modulated lasers: physics and application”, Proc. SPIE vol. 7953, pp. 79530F1-F10, 2011. As shown in the article, in the PFL laser, if the reflection feedback phase from the high reflection coated facet of the passive waveguide is properly chosen, a P-P resonance appears in the modulation response. Using this approach, the modulation bandwidth of 37 GHz was achieved. For the PFLs, numerical simulation based on the traveling-wave equations has been performed, which is described in the article, by M. Radziunas, A. Glitzky, U. Bandelow, M. Wolfrum, U. Troppenz, J. Kreissl, and W. Rehbein, “Improving the modulation bandwidth in semiconductor lasers by passive feedback”, IEEE J. Sel. Topic Quantum Electronics, vol. 13, no. 1, pp. 136-142, January/February 2007: The simulated modulation response shows the P-P resonance in the range of 40˜60 GHz, depending on the feedback phase, in addition to the E-P resonance.

The third approach is to use both the detuned loading effect and the P-P resonance effect, in the DR lasers composing of a DFB section and a DBR section. This is described, for example, in the article by Y. Matsui, R. Schatz, T. Pham, W. A. Ling, G. Carey, H. M. Daghighian, D. Adams, T. Sudo, and C. Roxlo, “50 GHz bandwidth distributed reflector laser,” J. Lightwave Technol., vol. 35, no. 3, pp. 397-403, Feb. 1, 2017. As shown in the article, in the DR laser with a high reflection (HR) coating on the DFB laser facet, if the cavity lengths of the two sections and the grating coupling coefficients are properly chosen, both the enhanced E-P resonance and the P-P resonance are obtained at the same time. The enhanced E-P resonance frequency of 30 GHz and the PP resonance frequency of 50 GHz were measured in the modulation response for the DR laser consisting of a DFB laser section of 50 μm and a DBR section of 200 μm. This achieved the modulation BW of 55 GHz. To provide a theoretical basis for the DR laser design, numerical simulation based on the transfer-matrix method together with multi-mode rate equations has been performed. The simulated modulation response shows both the enhanced E-P resonance at modulation frequency of 15˜40 GHz (which is a function of the injection current), and the P-P resonance at modulation frequency of around 60 GHz.

In the DR laser with high reflection (HR) coating on the DFB laser section facet (as described in the article cited above), the random variation of the grating phase at the facet may cause a variation of the P-P resonance frequency. To solve this problem, the DR laser structure composing of two DBRs, one of which plays a similar role to the HR, and two phase-shift regions, is proposed in the U.S. Pat. No. 10,063,032 B2 (hereafter the “'032 patent”). The simulation assuming the phase-shift amount of 103° in the center of the DFB laser section shows a P-P resonance peak at modulation frequency of around 80 GHz.

### SUMMARY

It is an object of the present invention to provide a distributed reflector (DR) semiconductor laser, comprising two cavity sections which are composed of a distributed feedback (DFB) section and a distributed Bragg reflector (DBR) section. The active region of the DR laser is formed of quantum dot (QD) layers and the two sections have separate electrodes. The QD layers in the DFB section provide optical gain, and the QD layers in the DBR section are biased just above transparent to provide a passive waveguide DBR.

The modulation bandwidth can be increased further beyond the limit of the conventional DFB lasers. The cavity lengths and the grating coupling coefficients of the two sections are properly chosen, which provide, the so called, “photon-photon (P-P) resonance,” in addition to the conventional relaxation resonance (the electron-photon (E-P) resonance). The P-P resonance frequency is much higher than the E-P resonance frequency, due to the external optical feedback from the DBR section. The E-P resonance frequency itself can be increased by the so called, “detuned loading effect,” due to the enhanced differential gain and the effective linewidth enhancement factor, if the lasing wavelength is chosen to be detuned from the peak of the DBR reflection spectrum.

The DFB section may have a length (denoted by Lₐ) in a range from 100 micrometer (μm) to 200 μm. The DFB laser grating may have a product of the grating coupling coefficient κₐ and the length Lₐ, that is, κₐLₐ in a range from 2˜6. The DBR section may have a length (denoted by Lₚ) in a range from 200 μm to 400 μm. The DBR grating may have a product of the grating coupling coefficient κₚ and the length Lₚ, that is, κₚLₚ in a range from 2˜6. The anti-reflection (AR) coating on the DFB laser facet is provided, which can reduce the variation of the PP resonance frequency due to a random variation in the grating phase at the DFB laser facet. The DFB cavity length of larger than 100 μm can provide a high output power from the AR coated DFB laser facet.

According to another aspect of the present invention, the laser contact through which a modulation signal may be provided is formed to have a coplanar electrode structure. Due to the superior microwave transmission performance of the coplanar structure, the parasitic effect, and the propagation attenuation of the modulation signal at very high frequencies can be reduced, for even longer cavity length of the DFB section (>100 μm).

The present DR laser has two main features: (1) enhanced modulation bandwidth that is much larger than the limit of the conventional direct modulation even for a relatively long cavity length (>100 μm); and (2) superior microwave characteristics of the modulation signal on the contact electrode. The first feature is provided by the so called “photon-photon (PP) resonance effect,” together with the so called “detuned loading effect.” The cavity lengths and the grating coupling coefficients of the two sections are chosen to exhibit the PP resonance, which is related to the optical feedback from the DBR section. The PP resonance frequency is much higher than the conventional relaxation (electron-photon (E-P)) resonance frequency. The lasing wavelength is chosen to be detuned from the peak of the DBR reflection spectrum (detuned loading), which results in the enhanced E-P resonance frequency due to the increase of the effective differential gain obtained on the slope of the DBR reflection spectrum. The second feature is provided by the coplanar electrode structure that can reduce the electric parasitic effects and the propagation attenuation of the modulation signal at very high frequencies.

### BRIEF DESCRIPTION OF THE DRAWINGS

Other systems, methods, features, and advantages of the present disclosure will be apparent to one skilled in the art upon examination of the following figures and detailed description. Component parts shown in the drawings are not necessarily to scale and may be exaggerated to better illustrate the important features of the present disclosure. In the drawings, like reference numerals designate like parts throughout the different views.

FIG. 1 is a cross-sectional view of a DR laser structure according to a first embodiment of the invention.

FIG. 2A is a calculated spectra as a function of the optical wavelength. The solid curve is the normalized amplified spontaneous emission (ASE) spectrum, and the dashed curve is the DBR reflection spectrum.

FIG. 2B is a calculated spectra as a function of the optical frequency. The solid curve is the normalized amplified spontaneous emission (ASE) spectrum, and the dashed curve is the DBR reflection spectrum.

FIG. 3 is a calculated amplitude modulation response as a function of modulation frequency, which is normalized by the modulation response at zero modulation frequency for the laser structure of FIG. 1.

FIG. 4 is a calculated amplitude modulation response as a function of modulation frequency, which is normalized by the modulation response at zero modulation frequency for the laser structure of FIG. 1. The linewidth enhancement factor is taken as a parameter.

FIG. 5 is a perspective view of a coplanar DR laser structure according to a second embodiment of the invention.

### DETAILED DESCRIPTION

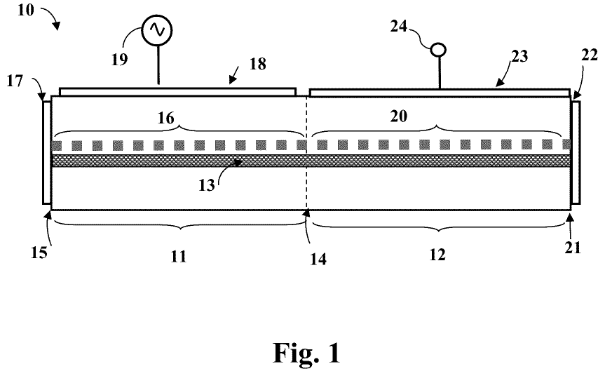

A cross section through a DR laser device 10 according to a first embodiment of the present invention is shown in FIG. 1. The laser cavity comprises two sections, a DFB section 11 and a DBR section 12. Both DFB section 11 and DBR section 12 may include a gain region 13, which is formed by using a quantum dot (QD) layer.

The DFB section 11 extends from the backside 14 to the frontside 15, having a length (denoted by Lₐ) in a range from 100 micrometer (μm) to 200 μm. A DFB grating 16 may have a product of the grating coupling coefficient κₐ and the length Lₐ, that is, κₐLₐ in a range from 2˜6. Anti-reflection (AR) coating 17 is deposited on the front side 15. The DFB section 11 has a contact 18, and a modulation signal 19 may be provided to the contact 18. In examples, the DBR section 12 may be coupled end to end with the DFB section 11, with the backside 14 of the DFB section 11 being coupled to the DBR section 12.

The DBR section 12 includes a QD layer (e.g., gain region 13), and a DBR grating 20 that extends from the frontside (indicated at the position of reference number 14) to the backside 21. The DBR section 12 has a contact 23, and a de bias current 24 may be provided. The length (denoted by Lₚ) of the DBR section 12 may be in a range from 200 μm to 400 μm. The product of the grating coupling coefficient κₚ and the length Lₚ, that is, κₚLₚ may be in a range from 2 to 6. An AR coating 22 is deposited on the backside 21. We denote the Bragg wavelengths of the DFB section 11 and the DBR section 12 as λ_{B-DFB} and λ_{B-DBR}, respectively. For example, λ_{B-DFB} may be selected as 1310 nm, and λ_{B-DBR} may be selected as λ_{B-DBR}=λ_{B-DEB}+Δλ_{B} with Δλ_{B}=−0.5˜0.5 nm. In examples, the gain region 13 may comprise a multiple quantum well (MQW) or quantum dots structure. Other configuration may be utilized in examples.

Lasers using QD active layers have demonstrated superior characteristics such as very low threshold currents, temperature insensitivity, and small linewidth enhancement factor, as is described in the article by Z. G. Lu, P. Poole, P. Barrios, Z. J. Jiao, J. R. Liu, G. Pakulski, D. Goodchild, B. Rioux, A. J. Springthorpe, and Poitras, “Single-mode 1.52 μm InAs/InP quantum dot DFB lasers,” OWD6.pdf, OSA OFC/NFOEC, 2011.

However, the maximum modulation speed of the DFB lasers using QD layers may not exceed 10 Gb/s operation. The optical confinement factor of the QD layers is low due to small active volumes, which results in low modal differential gain. Therefore, the PP resonance needs to be used in order to break the modulation speed limit set by the EP resonance. The advantage of using the QD layer in the DBR section 12 is that the waveguide loss of the DBR section 12 can be very small even if the bias current is not supplied, since the volume of the QD is very small.

Principles of operation, for a DR laser according to the first embodiment, are described in the following. The static characteristics (threshold gain, lasing wavelength, and sub-threshold spectrum) of the DR laser can be analyzed by a general model, described in the article, by T. Makino, “Transfer-matrix formulation spontaneous emission noise of DFB semiconductor lasers,” J. Lightwave Technol., vol. 9, no. 1, pp. 84-91, January 1991. The power spectrum of amplified spontaneous emission (ASE) emitted from the laser facets can be simulated efficiently using a transfer matrix that represents each section of a general multisection laser.

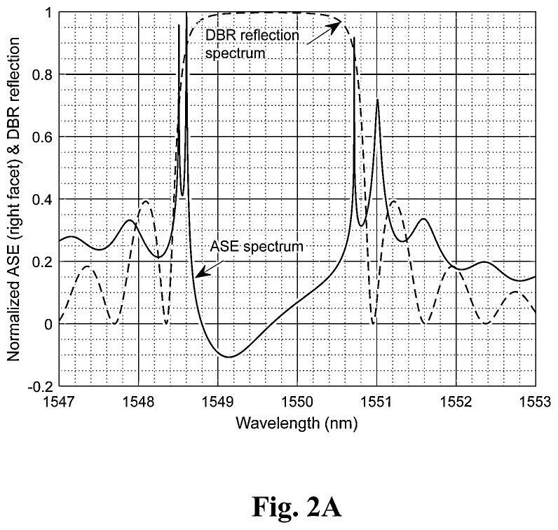

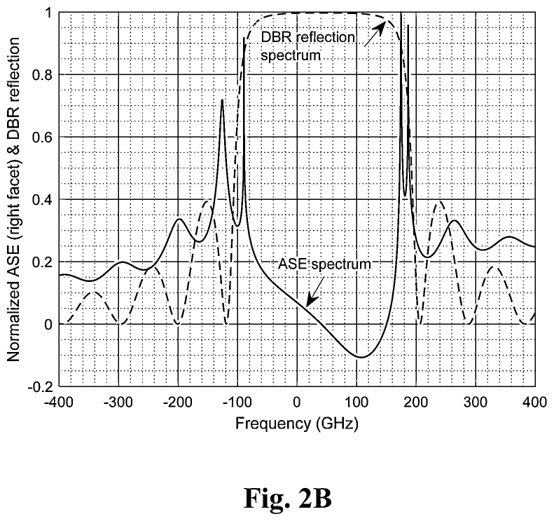

FIG. 2A shows calculated normalized ASE spectra as a function of the wavelength. FIG. 2B shows calculated normalized ASE spectra as a function of the optical frequency. The solid curve corresponds to the normalized ASE power spectral density emitted from the front facet of the DFB section below threshold for g/gₜₕ=0.99 where g and gin are the modal gain and its threshold value, respectively. The dashed curve corresponds to the DBR reflection spectrum. In this calculation, Lₐ=170 μm, κLₐ=3.7, Lₚ=350 μm, κLₚ=3.4, and the linewidth enhancement factor (Henry factor), α_{H}=3, are assumed. The Bragg wavelengths of the DFB and DBR gratings (denoted by λ_{B-DFB} and λ_{B-DBR}, respectively) are assumed as λ_{B-DFB}=1310 nm and λ_{B-DBR}=1310 nm-0.4 nm. The main mode is obtained at around 1309 nm with threshold modal gain g₁=32 cm⁻¹, and the side mode is obtained at around 1311 nm with threshold modal gain g₂=39 cm⁻¹. To maintain the side mode suppression ratio (SMSR) of larger than 30 dB under modulation, the normalized threshold gain difference, (g₂−g₁)/g₁>0.1 is usually required. In this example, we have (g₂−g₁)/g₁=0.22, which meets the requirement. It is noted in FIG. 2A that two external cavity modes appear close to the DFB modes (see FIG. 2A), which are somehow related to the PP resonance.

The dynamic characteristics can be described by the rate equations for the envelope of the electric field and the carrier numbers in the total cavity. The small-signal AM and FM modulation characteristics and the AM and FM noise characteristics are analyzed in the article by T. Makino, “Transfer-matrix theory of the modulation and noise of multielement semiconductor lasers”, IEEE J. Quantum Electron, vol. 29, no. 11, pp. 2762-2770 November 1993. If the modulation frequency becomes very high, the reflection feedback from the DBR section needs to be treated more accurately, since the phase of the DBR changes rapidly during the modulation. In this situation, the traveling-wave electric field needs to be used instead of the total electric field. The rate equation for the complex envelope function A⁺(t) of the forward (towards the DBR section) traveling-wave electric-field at the interface (see FIG. 1) can be derived. This includes the complex envelope function A⁻(t) of the backward (towards the DFB section) traveling-wave electric-field, which can be expressed as

$${A}^{-} ( t ) = {\int }_{- ∞}^{∞} ρ ( {t}^{′} ) {A}^{+} ( t - {t}^{′} ) {dt}^{′} \qquad ( 4 )$$

$$with$$

$$ρ ( t ) = \frac{1}{2 π} {\int }_{- ∞}^{∞} {r}_{Reff} ( ω ) {e}^{j ( ω - {ω}_{s} ) t} d ω \qquad ( 5 )$$

where r_{Reff} is the effective reflection coefficient looking at the interface 14 towards the DBR section, and ωₛ is the stationary value of the lasing angular frequency. The rate equations for the amplitude and phase of the complex envelope function A⁺(t) can be derived. When the DFB laser is modulated with modulation angular frequency 22, the optical angular frequency ω can be expressed as ω=ωₛ+Ω. Using this approach, the AM and FM noise of DFB lasers under external optical feedback from a simple (non-grating) reflector in distance has been analyzed, which is shown in the article by T. Makino, “Transfer-matrix analysis of the intensity and phase noise of multisection DFB semiconductor lasers,” IEEE J. Quantum Electron, vol. 27, no. 11, pp. 2404-2414 November 1991.

In the case of DR lasers, the reflector is a DBR, in which r_{R}_{_{eff}}(ω) is quite sensitive to Ω if ωₛ is located on the slope of the DBR grating spectrum (detuned loading), which makes ρ(t) quite sensitive to Ω. Applying this model, combining with the carrier rate equation, and assuming the small-signal modulation, we can analyze the modulation response in the frequency domain.

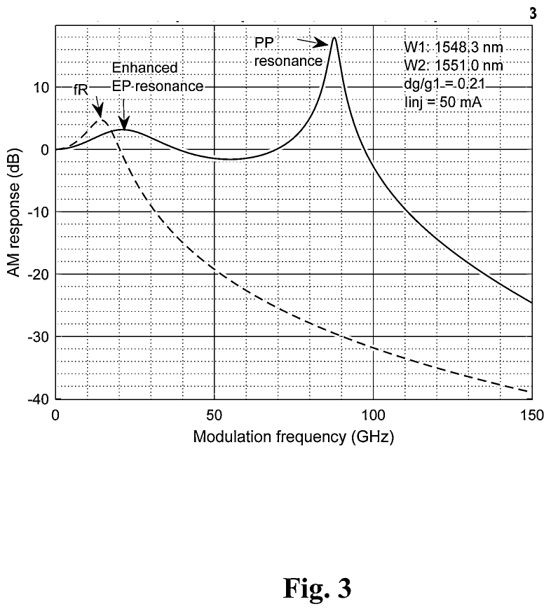

FIG. 3 shows a calculated amplitude modulation (AM) response as a function of the modulation frequency ƒ=ω/(2π). In this calculation, Lₐ=170 μm, κLₐ=3.7, Lₚ=350 μm, and κLₚ=3.4, and the linewidth enhancement factor, α_{H}=3, are assumed.

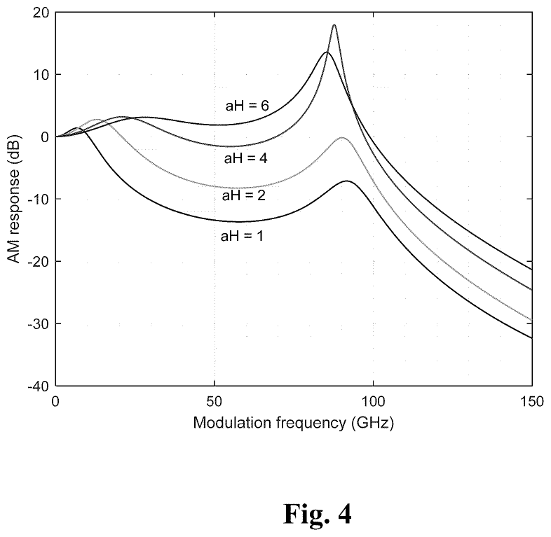

FIG. 4 shows calculated AM responses for different values of the linewidth enhancement factor (α_{H}=1, 2, 4, and 6). As we see in FIG. 4, the enhanced E-P resonance frequency increases as an increases, due to the detuned loading effect. The P-P resonance frequency is not much affected by α_{H}, although the P-P resonance peak magnitude increases. Therefore, both the enhanced E-P resonance and the P-P resonance can be simulated self consistently.

The validity of the present model used for the simulations in FIGS. 3 and 4 will be explained by comparing to the results of the previous approaches cited above in the followings:

For the DBR laser in the article described by Feiste, in which Lₐ=100 μm, Lₚ=400 μm and κLₚ=1.6 with cleaved facet (31% power reflection) are assumed, the PP resonance frequency of ˜60 GHz is obtained for the detuning wavelength of 0.604 nm (lasing wavelength-DBR reflection peak wavelength). The present model gives the PP resonance frequency of 65˜70 GHz for λ_{B-DBR}=1549.5 nm˜1549.3 nm.

For the passive feedback lasers (PFL) in the article described by Radziunas et al., in which Lₐ=250 μm, κLₐ=3.3, Lₚ=300 μm, and α_{H}=4 are assumed, the PP resonance frequency of ˜ 31 GHz is obtained for injection current of 60 mA. The present model gives the PP resonance frequency of ˜31 GHz for injection current of 60 mA for the same laser parameters.

For the DR lasers in the article described by Matsui et al., in which Lₐ=50 μm, Lₚ=200 μm, and HR coating (93% power reflection) are used, the measured PP resonance frequency of ˜ 50 GHz is obtained for injection current of ˜35 mA. As is pointed out in the '032 patent, the simulated PP resonance frequency is shown to vary according to the grating phase, which is one problem for this approach. In the present model, for Lₐ=50 μm, κLₐ=0.7, Lₚ=250 μm, κLₚ=4.8, α_{H}=4, λ_{B-DBR}=1310.1 nm (λ_{B-DFB}=1310 nm), and injection current of 35 mA, the PP resonance frequency of ˜83 GHz is obtained when the grating phase at the HR (90% power reflection) coated facet is selected as 300°. It is observed that the PP resonance frequency varies according to the grating phase. Considering that there are some uncertainties in the laser parameters, this value is reasonable compared to the value ˜50 GHz in the article described by Matsui et al. above. The present model gives the enhanced EP resonance frequency of ˜20 GHz (the solitary laser has the EP resonance frequency of ˜13 GHZ).

Next, the advantages of the present model will be explained in the following. The traveling-wave models used in the cited articles are the multi-mode models, which require to solve the multimode rate equations numerically. Therefore, the insight of laser parameter interplays is difficult to obtain. In the present model, the rate equations for the amplitude and phase of the envelope electric field of the laser structure are solved under the small-signal assumption, which gives analytical expressions for the AM and FM modulation responses. The appearance of the PP resonance and the enhanced EP resonance can be related directly to the phase sensitive DBR parameters together with the DFB laser parameters. The ASE spectrum below threshold is calculated for the DR whole structure, and the lasing threshold is found by searching the zeros of the inverse of the ASE intensity peaks, which correspond to the threshold gain and the stationary lasing wavelength. Therefore, the PP resonance effect and the detuned loading effect can be related to the sub-threshold spectrum characteristics self consistently.

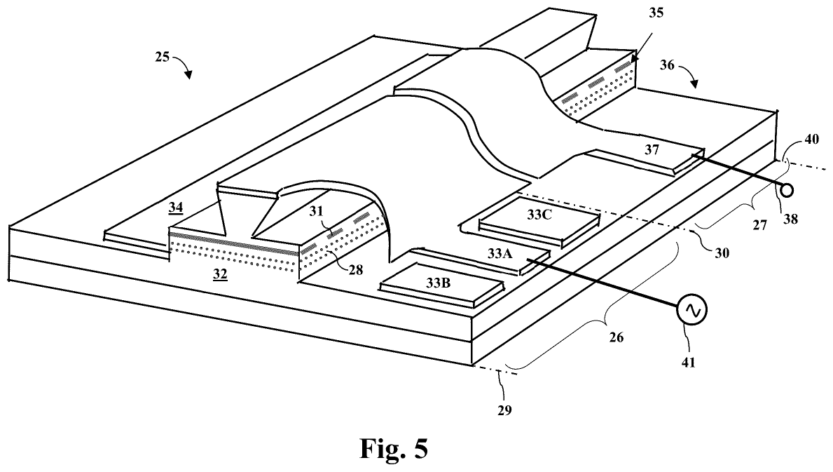

A second embodiment of a DR laser according to the present invention is described herein. FIG. 5 is a perspective view to show the construction of the second embodiment of a DR laser 25 according to the present invention. The schematic structure in FIG. 5 comprises a coplanar microwave transmission structure, which has superior performance at very high modulation frequencies. For larger length of the DFB laser cavity, the propagation of the microwave signals along the laser stripe, may cause a significant increase in the microwave attenuation, as is described in the article by D. Tauber and J. Bowers, “Dynamics of wide bandwidth semiconductor lasers”, International Journal of High Speed Electronics and Systems, vol. 8, no. 3, pp. 377-416, 1997. The approach using the coplanar electrode for single section DFB lasers is demonstrated and described, for example, in the article by Y-L Wu, J-P Wu, Y-J. Chiu, W. Lin, Y-H Wu, and R-T Hsu, “25 Gb/s directly modulation of 1550 nm DFB lasers with coplanar waveguide,” OECC 2012 Technical Digest, 5D3-3, July 2912, Busan, Korea. The modulation BW of larger than 20 GHz was achieved with cavity length of larger than 200 μm. Although the microwave performance is improved by the coplanar electrode, the maximum BW is still limited by the E-P resonance frequency. Therefore, the present invention can break the E-P resonance limit by making the PP resonance with adding a DBR to the DFB laser section.

In FIG. 5, the laser cavity comprises two sections, a DFB section 26 and a DBR section 27. The DFB section 26 may include a QD layer 28 that extends from the frontside 29 to the backside 30, having a length (denoted by Lₐ) in a range from 100 micrometer (μm) to 200 μm. A DFB grating 31 may have a product of the grating coupling coefficient κₐ and the length Lₐ, that is, κₐLₐ in a range from 2˜6. An anti-reflection (AR) coating 32 (its physical thickness not shown in FIG. 5) is deposited on the frontside 29. The electrodes 33A, 33B and 33C constitute a coplanar microwave transmission structure. An electrode 34 is the ground metal which is connected to the electrodes 33B and 33C. The contact electrode 33A is used for providing the modulation signal 41.

The DBR section 27 includes the QD layer 28, having a length (denoted by Lₚ) in a range from 200 μm to 400 μm. A DBR grating 35 is formed above the QD layer 28. The DBR grating 35 may have a product of the grating coupling coefficient κₚ and the length Lₚ, that is, κₚLₚ in a range from 2˜6. An AR coating 36 is deposited on the backside 40. The DBR section 27 has a contact electrode 37, to which a DC bias 38 may be applied to control the gain of the QD layer 28 in the DBR section 27. The reversed ridge structure assumed herein is similar to the article by Y-L Wu et al., cited above.

The present invention will be compared to the prior arts described in the Background of the Invention hereinafter. In the DBR laser approach, since the uniform active region is usually relatively long (100˜200 μm), several longitudinal modes exist within the DBR reflection band, which causes an ambiguity in the lasing wavelength accuracy. In the PFL approach, the passive waveguide has a HR coated facet, and its length is relatively long (˜200 μm). This creates a variation of the feedback phase, which in turn results in a variation of the P-P resonance frequency. In the DR laser approach, the approach of a short cavity DFB section with HR coating has a variation of the P-P resonance frequency due to the random variation of the grating phase at the HR facet. Although the approach of using two DBRs by replacing the HR by another DBR, is proposed (the '032 patent, cited above), this requires the phase shift in the center of the DFB laser section. The phase control for the P-P resonance may require a very high precision control of cavity lengths and grating pitches, as well as complicated fabrication process.

Considering the descriptions above, the first advantage of the present invention is that the cavity length of the DFB laser section to obtain the PP resonance with reasonable threshold current can be larger than 100 μm. The longer cavity length is also suitable for obtaining higher output power. For the DR lasers with DFB section length of 170 μm (which modulation response are shown in FIG. 3 and FIG. 4), the calculated ratio of the powers from the DFB facet end and the DBR facet end is 23 for I/Iₜₕ=2 (where I and Ith are the injection current and its threshold current).

The second advantage of the present invention is that the contact electrodes form a coplanar transmission line, which has superior microwave (to millimeter wave) performance at very high modulation frequencies for relatively longer cavity length of the DFB section.

The third advantage is that the active layers use the quantum dot layers which have superior characteristics in temperature insensitivity, and low loss under unpumped condition.

In examples, the DR lasers disclosed herein may include a lasing mode at either a long wavelength side or a short wavelength side of a peak of a DBR reflection profile of the DBR section.

In examples, the DR lasers disclosed herein may have a photon-photon resonance frequency larger than 50 GHz.

Exemplary embodiments of the methods/systems have been disclosed in an illustrative style. Accordingly, the terminology employed throughout should be read in a non-limiting manner. Although minor modifications to the teachings herein will occur to those well versed in the art, it shall be understood that what is intended to be circumscribed within the scope of the patent warranted hereon are all such embodiments that reasonably fall within the scope of the advancement to the art hereby contributed, and that that scope shall not be restricted, except in light of the appended claims and their equivalents.

What is claimed is:

1. A distributed reflector (DR) laser, comprising:
a distributed feedback (DFB) section having a length in a range from 100 micrometers (μm) to 200 μm and comprising a DFB grating with a product of grating coupling coefficient kappa (κ) and a cavity length (L), κL, in a range from 2 to 6; and
a distributed Bragg reflector (DBR) section coupled end to end with the DFB section, having a length in a range from 200 μm to 400 μm, and comprising a DBR grating with a product of grating coupling coefficient kappa (κ) and a cavity length (L), κL, in a range from 2 to 6.

2. The DR laser of claim 1, wherein the DR laser comprises a coplanar electrode for applying a modulation signal.

3. The DR laser of claim 1, wherein the DFB section has a front side and a backside, the backside of the DFB section being coupled to the DBR section, the DR laser further comprising an anti-reflection (AR) coating formed on the front side of the DFB section.

4. The DR laser of claim 1, wherein the DFB section comprises a multiple quantum well (MQW) structure.

5. The DR laser of claim 1, wherein the DFB section comprises a quantum dots structure.

6. The DR laser of claim 1, further comprising a lasing mode at either a long wavelength side or a short wavelength side of a peak of a DBR reflection profile of the DBR section.

7. The DR laser of claim 6, wherein the DR laser has a photon-photon resonance frequency larger than 50 GHz.

8. The DR laser of claim 1, further comprising a contact for providing a dc bias current to the DBR section.

9. The DR laser of claim 1, wherein the DFB section includes a quantum dot layer that extends from a front side of the DFB section to a backside of the DFB section.

10. The DR laser of claim 1, wherein the quantum dot layer extends from a front side of the DFB section to a backside of the DBR section.
